(19) United States
(12) Patent Application Publication
(10) Pub. No.: US 2001/0049212 A1
(43) Pub. Date: Dec. 6, 2001

(54) Low profile connector for printed wire boards

(76) Inventor: Jaime R. Arnett, Fishers, IN (US)

Correspondence Address: Law Office of Leo Zucker, 50 Main Street Suite 480, White Plains, NY, 10606-1975, US

(21) Appl. No.: 09/542,581

(22) Filed: Apr. 4, 2000

(51) Int. Cl. H05K 1/00

(52) U.S. Cl. 439/79

(57) ABSTRACT

A wire board connector has a connector body of generally rectangular form. The body has a pair of side walls and first locating members extending from the side walls. The members are arranged to adjoin a first surface of a wire board having a mounting slot cut into an edge of the board, within which slot the connector body is to be mounted. Second locating members extending from the side walls of the body are arranged to adjoin a second surface of the board opposite the first surface when the connector body is mounted in the mounting slot. The connector body is restrained from movement by the locating members in directions normal to the wire board. Terminals supported by the connector body are provided for establishing contact between a mating connector and components of the wire board.

### BACKGROUND OF THE INVENTION

1. Field of the Invention

This invention relates to connectors for use with printed wire boards.

2. Discussion of the Known Art

Miniaturization is an important factor in the success of consumer electronics products such as, e.g., laptop computers, portable audio cassettes/compact disk players, and cellular telephones. In electronics products that incorporate a printed wire board, jack connectors are typically mounted on the board to facilitate connections with telephone lines, networks, power supplies, or the like. Typical jack. connectors that are used with wire boards require an overall height of the product to be at least as tall as the height of the jack, plus the sum of the thickness of the wire board and the height of any splines on which the jack is seated on the board. Thus, the known wire board jack connectors impose a certain minimum size dimension on the product, which could diminish both the appeal and potential applications of a new product in the marketplace.

### SUMMARY OF THE INVENTION

According to the invention, a printed wire board connector includes a connector body of generally rectangular form. The body has a pair of side walls and first locating members extending from the side walls. The locating members are formed and arranged to adjoin a first surface of a wire board that has a mounting slot cut into an edge of the board, and in which slot the connector body is to be mounted. Second locating members extending from the body side walls are formed and arranged to adjoin a second surface of the board opposite the first surface when the connector body is mounted in the board slot. The connector body is restrained from movement by the locating members in directions normal to the surfaces of the wire board. One or more terminals supported by the connector body serve to establish contact between a mating connector and components of the wire board.

For a better understanding of the invention, reference is made to the following description taken in conjunction with the accompanying drawing and the appended claims.

### BRIEF DESCRIPTION OF THE DRAWING

In the Drawing

FIG. 1 is a perspective view of a first embodiment of a connector according to the invention, as seen from the top of a wire board in which the connector is mounted;

FIG. 2 is a perspective view of the connector of FIG. 1 as seen from the bottom of the wire board;

FIG. 3 is a side view of the connector in FIG. 1, showing a first arrangement of connector terminals supported in the connector body;

FIG. 4 is a side view of the connector in FIG. 1, showing a second arrangement of connector terminals supported in the connector body;

FIG. 5 is a side view of the connector in FIG. 1, showing a third arrangement of connector terminals supported in the connector body; and

FIG. 6 is a perspective view of a second embodiment of a connector according to the invention, as seen from the top of a wire board in which the connector is mounted.

### DETAILED DESCRIPTION OF THE INVENTION

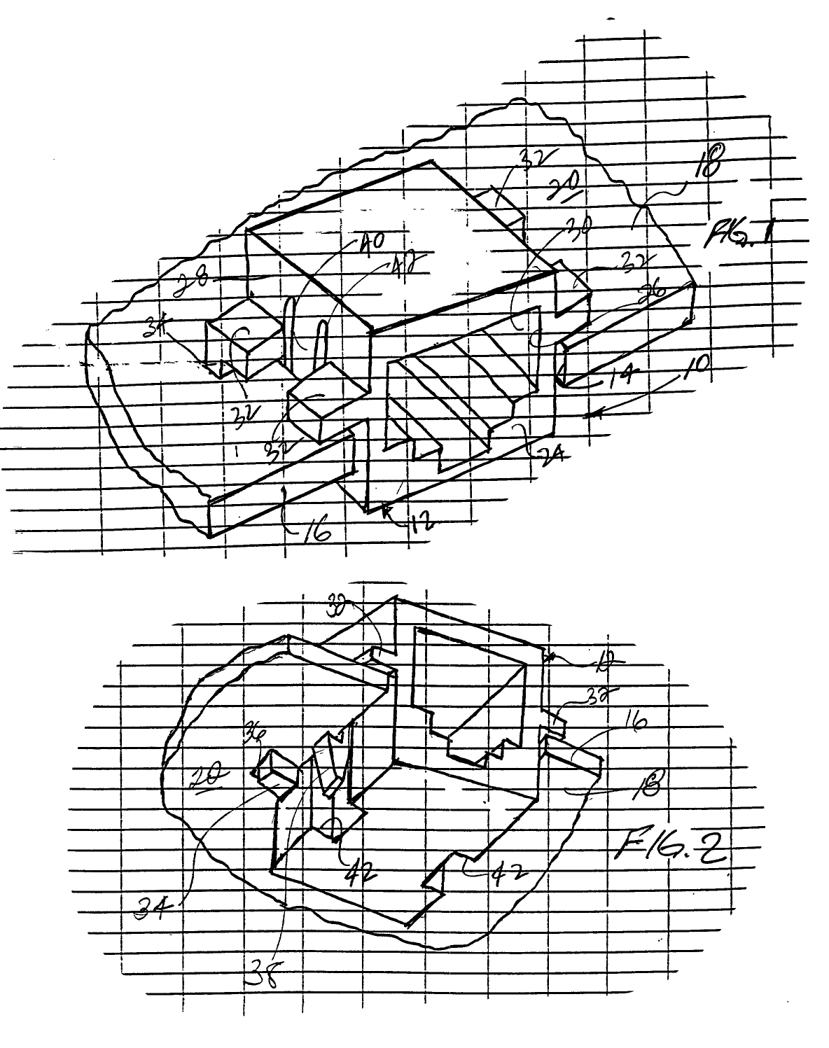

FIGS. 1 and 2 show a first embodiment of a connector 10 according to the invention. The connector 10 has a connector body 12 of generally rectangular overall form. The body 12 is mounted within a rectangular slot 14 that opens on an edge 16 of a printed wire board 18. The connector body 12 may be made of an electrically insulative or plastics material meeting all applicable standards for electrical insulation and flammability. Typical materials for the connector body 12 include, e.g., polycarbonate, ABS, and blends thereof. In this embodiment, the connector body 12 is mounted in place on the wire board 18 by urging the body vertically downward into the slot 14 from above the board 18.

The wire board 18 has a top or first surface 20, and a bottom or second surface 22 which can be seen in FIG. 2. The wire board may also have conductive wire traces (not shown in the drawing) on either the top or the bottom surfaces 20, 22, as well as on surfaces between the top and the bottom ones if the board 18 is a multi-layer printed wire board. The connector 10 allows such printed wire traces, or any other discrete components associated with the board 18, to be connected electrically with outside circuits, such as, e.g., telephone lines, power adapters, external networks, and the like.

The present connector 10 is not limited to electrical applications, however, and may be used in fiber optic applications involving the board 18, as well. For purposes of illustration and without limitation, FIGS. 4-6, described below, show various arrangements of electrical connector terminals supported by the connector body 12.

The connector body has a front wall 24, and a plug opening 26 in the front wall 24. The plug opening 26 is dimensioned to receive a mating plug connector (not shown) so that connector terminals supported by the body inside the plug opening 26 establish contact with corresponding terminals of the mating plug connector. In the illustrated embodiment, the plug opening 26 is configured to accept existing types of telephone or wire network plugs.

The connector body has a pair of side walls 28, 30, which align with side edges of the rectangular slot 14, when the connector body 12 is mounted within the slot as shown in FIGS. 1 and 2. A first set of locating members 32 extend outwardly of the side walls 28, 30, and are formed and arranged on the side walls to overlie the top surface 20 of the wire board 18. Accordingly, the connector body 12 is restrained from downward movement relative to the wire board 18 in FIGS. 1 and 2, by the locating members 32 which adjoin the top surface 20 of the wire board in the vicinity of the edge of the board slot 14.

A rib 34 projects downward from the member 32 at the upper left in FIG. 1, and the rib 34 is received in a notch 36 cut in the wire board 18 (see FIG. 2). When the rib 34 engages the notch 36, the connector 10 is prevented from being pulled longitudinally out of the slot 14, for example, when tension is applied to a wire cord having a plug that is mated with the connector 10.

A second set of locating members 38 are formed and arranged to extend outwardly of the side walls 28, 30 of the connector body, to overlie the bottom surface 22 of the board when the connector body 12 is urged into the slot 14. In the embodiment of FIGS. 1 and 2, the members 38 (one of which is shown in FIG. 2) are formed at lower free ends of resilient vertical tongues 40 that are fixed at the tops of vertical channels 42 formed in the side walls 28, 30 of the connector body 12. The tongues 40 are based to extend angularly outward of the connector body.

As shown in FIG. 2, each member 38 is in the form of a ratchet tooth or snap having an inclined leading surface so that when the connector body 12 is urged into the slot 14 from above the wire board 18, the members 38 slide against the side edges of the slot and are urged with the associated tongues 40 into the body side wall channels 42. When the first locating members 32 abut the top surface 20 of the wire board, the second members 38 are below the side edges of the slot and snap outward to overlie the bottom surface 22 of the board. Thus, the connector body 12 is restrained from upward movement relative to the wire board 18 by the second set of locating members 38 adjoining the bottom surface 22 of the board.

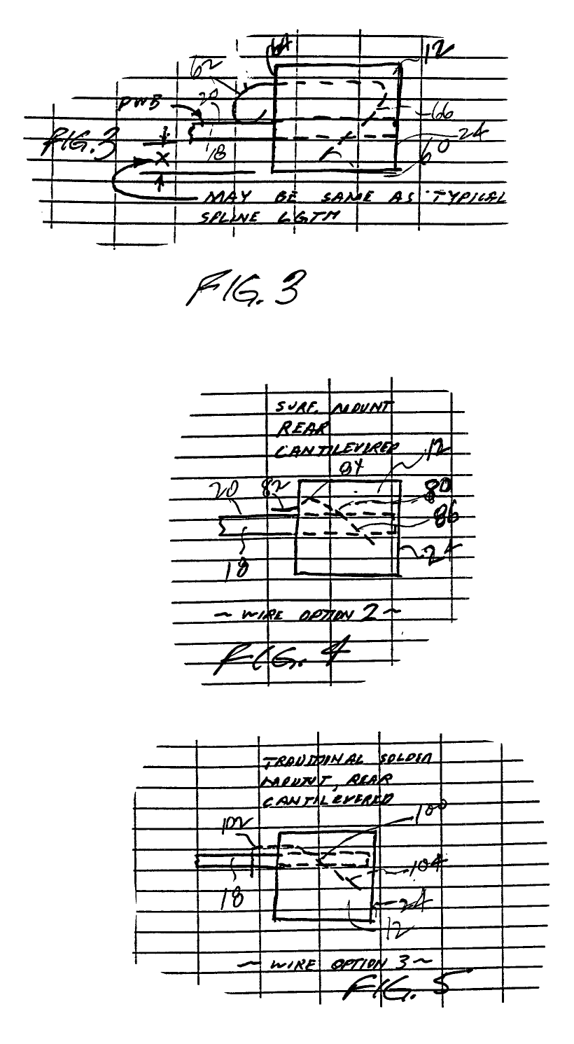

FIG. 3 is a side view of the connector 10, showing a first arrangement of one or more connector terminals 60 supported inside the connector body 12. Rear portions 62 of the connector terminals exit from a back wall 64 of the connector body, and arc downwardly to contact corresponding conductive pads on the top surface 20 of the wire board 18. See U.S. Pat. No. 4,688,875 issued Aug. 25, 1987. All relevant portions of the '875 patent are incorporated by reference. Front portions 66 of the terminals 60 bend inwardly with respect to the front wall 24 of the connector body, and establish electrical contact with corresponding terminals of a mating connector.

FIG. 4 is a side view of the connector 10, showing a second arrangement of connector terminals 80 supported inside the connector body 12. The terminals 80 in FIG. 4 are shorter relative to the terminals 60 in the arrangement of FIG. 3, for enhanced data transmission characteristics. Rear portions 82 of the terminals exit the back wall of the connector body and establish a solderless, surface mount connection with corresponding contact pads on the top surface 20 of the wire board. The terminals 80 are arranged inside the plug opening 26 in a rear cantilever fashion, with rear end parts 84 of the terminals pivoted against an upper wall of the plug opening 26. Front portions 86 of the terminals incline downwardly toward the front wall 24 of the connector body to establish electrical contact with corresponding terminals of a mating connector.

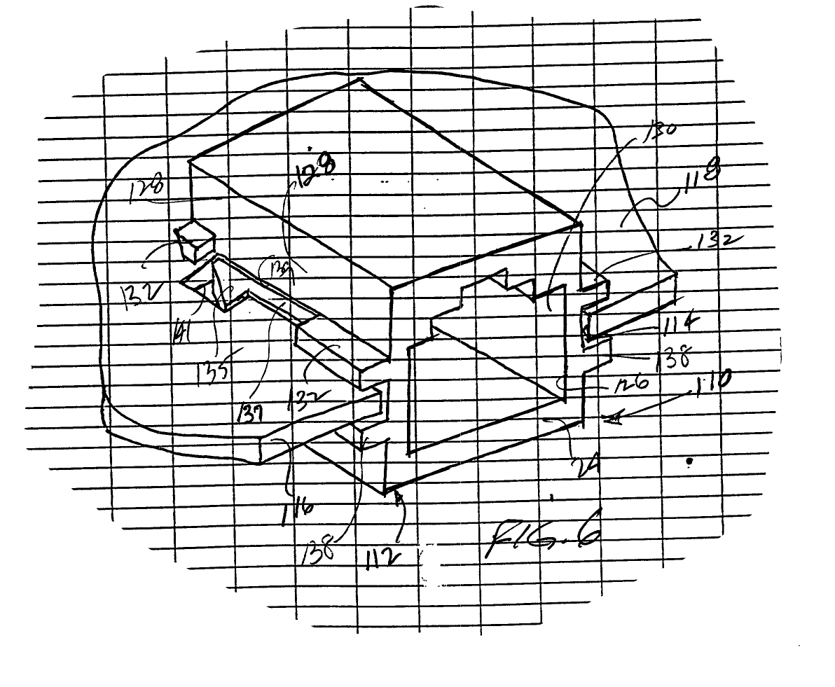

FIG. 5 is a side view of the connector 10, showing a third arrangement of connector terminals 100 supported inside the connector body 12. The terminals 100 in FIG. 5 are shorter than those typically used in printed wire board jacks. Rear portions 102 of the terminals are formed to be soldered in corresponding terminal openings on the wire board 14. As in the arrangement of FIG. 4, front portions 104 of the terminals incline downwardly toward the front wall 24 of the connector body to establish electrical contact with corresponding terminals of a mating connector.

FIG. 6 is perspective view of a second embodiment of a connector 110 according to the invention. Parts the same or similar to those of the embodiment in FIGS. 1 and 2, have the same reference numerals increased by 100.

The FIG. 6 embodiment differs from that of FIGS. 1 and 2 in that the connector body 112 is mounted on the wire board 118 by sliding the connector body into the slot 114 from the edge 116 of the board. A first set 132 of locating members extend outward from the side walls 128, 130 of the connector body. A second set of locating members 138 extend from the side walls and are spaced from the first set 132 by an amount sufficient to allow the side edges of the slot 114 to slide between the first and the second locating members 132, 138. Thus, the locating members 132, 138 restrain movement of the connector body 112 in directions normal to the surfaces of the wire board 118.

A ratchet tooth or snap 135 having an inclined leading surface is formed at a free end of a resilient tongue 137 that is fixed at a front end in a longitudinal channel 139 in each of the body side walls 128, 130. Each tongue 137 is biased to extend angularly outward of the connector body. The wire board 118 has notches 141 cut at the rear of the side edges of the slot 114.

Accordingly, as the connector body 112 is inserted in the board slot 114 from the edge 116 of the board, the snap 135 at each side of the body is initially urged into the side channels 139 until the connector body is fully inserted in the slot 114. At that position, each snap 135 is urged outward by the tongues 137 into a corresponding notch 141. The connector body 112 is thus restrained from being pulled horizontally out from the slot 114.

Both embodiments of FIGS. 1 and 6 may apply a “lock-in” feature, wherein a mating plug will act to prevent the snaps 38 or 135 from inadvertently disengaging the wire board. See, e.g., U.S. Pat. No. 5,041,018 issued Aug. 20, 1991, all relevant portions of which are incorporated by reference. Either of the connector terminal arrangements of FIGS. 3 and 4 may be incorporated in the connector body 110 in FIG. 6. The FIG. 5 terminal arrangement may not, however, be appropriate for the FIG. 6 embodiment if the rear portions 102 of the terminals are initially bent downward to enter terminal openings in which they are to be soldered, i.e., the rear portions 102 may strike the rear edge of the slot 114 when the connector 110 is inserted in the slot from the board edge 116.

While the foregoing description represents preferred embodiments of the invention, it will be obvious to those skilled in the art that various changes and modifications may be made, without departing from the spirit and scope of the invention pointed out by the following claims.

I claim:

1. A printed wire board connector, comprising:
a connector body having a generally rectangular form, the body having a pair of side walls and first locating members extending from the side walls;
the first locating members are formed and arranged to adjoin a first surface of a wire board having a mounting slot cut into an edge of the board, within which slot the connector body is to be mounted;
second locating members extending from the side walls of the connector body;
the second locating members are formed and arranged to adjoin a second surface of the wire board opposite the first surface when the connector body is mounted in said slot, so that the connector body is restrained from movement by said locating members in directions normal to the surfaces of the wire board; and
one or more connector terminals supported by the connector body for establishing contact between a mating connector and components of the wire board.

2. A connector according to claim 1, wherein at least one second locating member is in the form of a resilient snap having an inclined leading surface, so that when the connector body is urged into the mounting slot from above the wire board the snap is urged toward the connector body to clear side edges of the slot until the body is at a mounting position, whereat the snap is urged outward to adjoin the second surface of the board.

3. A connector according to claim 1, including a rib fixed to the connector body which rib is located and dimensioned to engage a notch cut in the wire board when the connector body is mounted on the board, for restraining movement of the connector body horizontally out of the mounting slot in the board.

4. A connector according to claim 1, including at least one resilient snap fixed to the connector body, the snap having an inclined surface so that when the connector body is inserted in the mounting slot from the edge of the wire board, the snap is urged toward the connector body to clear side edges of the slot until the body is at a mounting position, whereat the snap is urged outward to engage a notch cut in the wire board thus restraining movement of the connector body horizontally out of the mounting slot in the board.

5. A connector according to claim 1, wherein the connector body has a front wall, and a plug opening in the front wall which opening is configured to receive a mating plug connector so that said connector terminals establish contact with the plug connector inside the plug opening.

6. A connector according to claim 5, wherein the connector terminals have front portions that bend inwardly with respect to the front wall of the connector body for contacting corresponding terminals of a mating connector.

7. A connector according to claim 6, wherein the connector body has a back wall, and the connector terminals have rear portions that exit from the back wall and arc downward for contacting corresponding pads on the first surface of the wire board.

8. A connector according to claim 5, wherein the connector terminals are supported by the connector body inside the plug opening in rear cantilever fashion, and front portions of the terminals incline downward toward the front wall of the connector body for contacting corresponding terminals of a mating connector.

9. A connector according to claim 8, wherein the connector body has a back wall, and the connector terminals have rear portions that exit from the back wall, and are configured to establish a surface mount connection with corresponding pads on the first surface of the wire board.

10. A connector according to claim 8, wherein the connector body has a back wall, and the connector terminals have rear portions that exit from the back wall and are formed to be soldered in corresponding terminal openings in the wire board.
